(19) United States
(12) Patent Application Publication
(10) Pub. No.: US 2025/0277149 A1
(43) Pub. Date: Sep. 4, 2025

(54) ETCHING COMPOSITION AND METHOD FOR MANUFACTURING SEMICONDUCTOR DEVICE USING THE SAME

(71) Applicants: Samsung Electronics Co., Ltd., Suwon-si (KR); BASF SE, Ludwigshafen am Rhein (DE)

(72) Inventors: Bongkyun KANG, Suwon-si (KR); Andreas KLIPP, Ludwigshafen am Rhein (DE); Minhyung CHO, Suwon-si (KR); Jinhye BAE, Suwon-si (KR); Jung-Min OH, Suwon-si (KR); Geonja LIM, Seongnam-si (KR); Sang Won BAE, Suwon-si (KR); Hyosan LEE, Suwon-si (KR)

(73) Assignees: Samsung Electronics Co., Ltd., Suwon-si (KR); BASF SE, Ludwigshafen am Rhein (DE)

(21) Appl. No.: 18/868,189

(22) PCT Filed: May 27, 2022
(86) PCT No.: PCT/KR2022/007584

§ 371 Date: Nov. 22, 2024

(51) Int. Cl. C09K 13/00; H01L 21/311

(52) U.S. Cl. CPC C09K 13/00; H01L 21/31116; H01L 21/31144

(57) ABSTRACT

According to the inventive concept, an etching composition includes about 20 wt % to about 30 wt % of an oxidizer, a buffer including at least one among ammonium phosphate and a material represented by Formula 1, and a pH adjustor including alkyl ammonium hydroxide, wherein the etching composition may have a pH of 7 to 9.

### TECHNICAL FIELD

The present disclosure herein relates to an etching composition and a method for manufacturing a semiconductor device using the same.

### BACKGROUND ART

In order to satisfy excellent performance and affordable price required by consumers, the increase of the integration degree and the improvement of reliability of semiconductor devices are being required. With the increase of the integration degree of semiconductor devices, damages of constituent elements of the semiconductor devices during the manufacturing process of semiconductor devices influence a lot to the reliability and electrical properties of the semiconductor memory devices. Particularly, during the manufacturing process of semiconductor devices, the maintenance of a high etching selectivity of an etching target layer with respect to other layers is required.

### DISCLOSURE OF INVENTION

### Technical Problem

The task for solving of the present disclosure is to provide an etching composition having a high etching selectivity.

### Solution to Problem

The inventive concept relates to an etching composition and a method for manufacturing a semiconductor device using the same. According to embodiments of the inventive concept, an etching composition includes about 20 wt % to about 30 wt % of an oxidizer; a buffer including at least one among ammonium phosphate and a material represented by Formula 1 below; and a pH adjustor including alkyl ammonium hydroxide, wherein the etching composition may have a pH of 7 to 9.

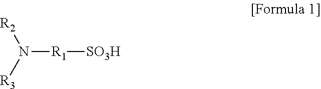

In Formula 1, R₁ is alkyl of 1 to 8 carbon atoms, R₂ and R₃ are each independently hydrogen, alkyl of 1 to 3 carbon atoms, or hydroxyalkyl of 1 to 8 carbon atoms, or R₂ and R₃ are connected with each other to form a heterocyclic structure of 2 to 8 carbon atoms, and in Formula 1, at least one among R₂ and R₃ is hydroxyalkyl of 1 to 8 carbon atoms, or R₂ and R₃ have a connected heterocyclic structure of 2 to 8 carbon atoms with each other.

According to embodiments of the inventive concept, an etching composition includes about 20 wt % to about 30 wt % of an oxidizer; a buffer including at least one among ammonium phosphate and a material represented by Formula 1 below, wherein a concentration of the buffer is about 1 wt % to about 10 wt %; a pH adjustor including alkyl ammonium hydroxide, wherein a concentration of the pH adjustor is about 3 wt % to about 10 wt %; a corrosion inhibitor including substituted or unsubstituted benzotriazole, wherein a concentration of the corrosion inhibitor is about 0.1 wt % to about 10 wt %; a chelating agent including a carboxylate group or a phosphonate group, wherein a concentration of the chelating agent is about 0.1 wt % to about 3 wt %; and a solubilizer including a polar aprotic organic solvent, wherein a concentration of the solubilizer is about 15 wt % to about 25 wt %, wherein the etching composition has a pH of 7 to 9.

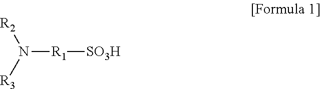

In Formula 1, R₁ is alkyl of 1 to 8 carbon atoms, R₂ and R₃ are each independently hydrogen, alkyl of 1 to 3 carbon atoms, or hydroxyalkyl of 1 to 8 carbon atoms, or R₂ and R₃ are connected with each other to form a heterocyclic structure of 2 to 8 carbon atoms, and in Formula 1, at least one among R₂ and R₃ is hydroxyalkyl of 1 to 8 carbon atoms, or R₂ and R₃ have a connected heterocyclic structure of 2 to 8 carbon atoms with each other.

According to embodiments of the inventive concept, a method for manufacturing a semiconductor device, includes: preparing a substrate, a first insulating layer on the substrate, a metal pattern on the first insulating layer, an etch stop layer covering a top surface of the metal pattern, a second insulating layer on the first insulating layer, and a mask pattern on the top surface of the second insulating layer; performing a first etching process on the top surface of the second insulating layer exposed by the mask pattern to form an opening exposing the etch stop layer; and performing a second etching process using the etching composition according to embodiments with respect to the mask pattern and in the opening to remove the mask pattern, wherein the mask pattern may have an etching selectivity with respect to the etch stop layer during the second etching process.

### Advantageous Effects of Invention

According to the inventive concept, the etching composition may have a high etching selectivity of titanium nitride with respect to cobalt, copper or aluminum oxide. Accordingly, the yield of the manufacturing process of a semiconductor device may be improved.

### BRIEF DESCRIPTION OF DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 to FIG. 6 are drawings for explaining the method for manufacturing a semiconductor device according to embodiments.

### MODE FOR THE INVENTION

In the disclosure, hydrocarbon may include saturated hydrocarbon and unsaturated hydrocarbon. The saturated hydrocarbon may include chain-type saturated hydrocarbon and cyclic saturated hydrocarbon. The unsaturated hydrocarbon may include chain-type unsaturated hydrocarbon and cyclic unsaturated hydrocarbon.

The term “substituted or unsubstituted” corresponds to substituted or unsubstituted with one or more substituents selected from the group consisting of a deuterium, a halogen atom, a cyano group, a nitro group, an amino group, an oxide group, a phosphine sulfide group, a thiol group, a carboxyl group, an amine group, an amide group, an alkyl group, an alkenyl group, an aryl group and a heterocycle. In detail, the term “substituted or unsubstituted” corresponds to substituted or unsubstituted with one or more substituents selected from the group consisting of a deuterium atom, alkyl of 1 to 4 carbon atoms, amino alkyl of 1 to 4 carbon atoms, phenyl, thiophenyl, halogen, hydroxyl, nitro, and thiol. In addition, each of the example substituents may be substituted or unsubstituted. For example, a methyl amino group may be interpreted as an amino group.

In the disclosure, examples of a halogen atom may include a fluorine atom, a chlorine atom, a bromine atom or an iodine atom. In the disclosure, an alkyl group may be a linear alkyl group, a branched alkyl group, or a cyclic alkyl group. The carbon number of the alkyl group is not specifically limited, but may be an alkyl group of 1 to 8 carbon atoms, particularly, an alkyl group of 1 to 4 carbon atoms.

In the disclosure, the carbon number of an amino group is not specifically limited, but may be 1 to 8, particularly, 1 to 4. The amino group may include an alkyl amino group and an aryl amino group.

In the chemical formulae in the disclosure, in the case where a chemical bond is not drawn where a chemical bond is necessary, it may mean that a hydrogen atom is bonded at that position, unless otherwise defined.

Hereinafter, an etching composition and the manufacture of a semiconductor device using the same according to the inventive concept will be explained.

According to the inventive concept, the etching composition may include an oxidizer, a pH adjustor, a buffer, a corrosion inhibitor, a solubilizer, a stabilizer and water. The polishing target of the etching composition may include a metal or a metal nitride. For example, the etching composition may be used for removing a hard mask layer, and the hard mask layer may include a metal material such as titanium nitride. Hereinafter, a case where the etching target includes a metal nitride will be explained, but embodiments of the inventive concept is not limited thereto.

The oxidizer may include at least one among hydrogen peroxide, peroxide urea, peroxydisulfuric acid, ammonium persulfate, peroxymonosulfuric acid, pyrosulfuric acid, ozone and mixtures thereof. The etching composition may include a relatively high amount of the oxidizer. For example, the concentration of the oxidizer may be about 20 wt % to about 30 wt %.

The oxidizer may oxidize a polishing target (e.g., titanium nitride layer) during an etching process. For example, the oxidizer may oxidize titanium nitride into titanium oxide or titanium oxynitride. The titanium oxide may have a higher solubility than the titanium nitride in water or an organic solvent. Accordingly, the titanium nitride may be removed even more easily.

The pH adjustor may include alkyl ammonium hydroxide. For example, the pH adjustor may be represented by [NR₁₁R₁₂R₁₃R₁₄]OH. Here, R₁₁, R₁₂, R₁₃, and R₁₄ may be each independently hydrogen or substituted or unsubstituted alkyl of 1 to 6 carbon atoms. For example, R₁₁, R₁₂, R₁₃, and R₁₄ may be each independently hydrogen or substituted or unsubstituted alkyl of 1 to 4 carbon atoms. The alkyl ammonium hydroxide may include tetraalkyl ammonium hydroxide. For example, the pH adjustor may include tetramethyl ammonium hydroxide or tetraethyl ammonium hydroxide. The concentration of the pH adjustor may be about 3 wt % to about 10 wt %, particularly, about 4 wt % to about 7 wt %. The pH adjustor may not include a metal.

The etching composition may include the pH adjustor and may have a pH of 6 to 12. For example, the pH of the etching composition may be 7 to 9. If the pH of the etching composition is less than 6, a corrosion inhibitor may be hard to dissolve in the etching composition. Since the pH of the etching composition is 6 or more, the solubility of the corrosion inhibitor in the etching composition may increase.

A buffer may include an ammonium salt of a weak acid. According to embodiments, the buffer may be any one among ammonium phosphate and a material represented by Formula 1 below. For example, ammonium phosphate may include at least one among diammonium hydrogen phosphate ((NH₄)₂HPO₄), ammonium dihydrogen phosphate ((NH₄)H₂PO₄), and triammonium phosphate ((NH₄)₃PO₄).

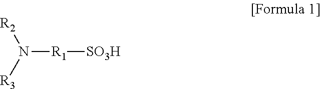

In Formula 1, R₁ is alkyl of 1 to 8 carbon atoms, R₂ and R₃ are each independently hydrogen, alkyl of 1 to 3 carbon atoms, or hydroxyalkyl of 1 to 8 carbon atoms, or R₂ and R₃ are connected with each other to form a heterocyclic structure of 2 to 8 carbon atoms, and in Formula 1, at least one among R₂ and R₃ is hydroxyalkyl of 1 to 8 carbon atoms, or R₂ and R₃ have a connected heterocyclic structure of 2 to 8 carbon atoms with each other.

In Formula 1, the heterocyclic structure may include at least one among O and N.

In Formula 1, if R₂ or R₃ is hydroxyalkyl, R₂ or R₃ may be alkyl which is substituted with multiple hydroxyl groups. The alkyl may be tertiary alkyl. In this case, R₂ or R₃ may be alkyl which is substituted with three hydroxyl groups.

For example, R₂ may be hydrogen, and R₃ may be alkyl which is substituted with a hydroxyl group.

For example, the material represented by Formula 1 may include at least one among a material represented by Formula 1A, a material represented by Formula 1B, and a material represented by Formula 1C.

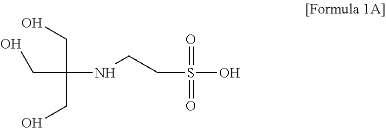 [SMILES: O=S(=O)(O)CCNC(CO)(CO)CO]

The material represented by Formula 1A may be N-[tris(hydroxymethyl)methyl]-2-aminoethansulfonic acid (TES).

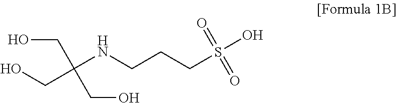 [SMILES: O=S(=O)(O)CCCNC(CO)(CO)CO]

The material represented by Formula 1B may be N[tris(hydroxymethyl)methyl]-3-aminopropanesulfonic acid (TABS).

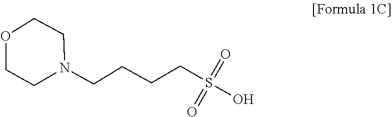 [SMILES: O=S(=O)(O)CCCCN1CCOCC1]

The material represented by Formula 1C may be 4-(N-morpholino)butanesulfonic acid (MOBS).

The buffer may stabilize the pH of the etching composition. For example, though the etching composition includes about 20 wt % to about 30 wt % of the oxidizer, the pH of the etching composition may be stabilized to 7 to 9 due to the buffer. The etching rate of the etching composition with respect to a titanium nitride layer may be improved due to the buffer.

The concentration of the buffer may be about 1 wt % to about 10 wt %, particularly, about 1.5 wt % to about 5 wt %. Since the concentration of the buffer satisfies the aforementioned conditions, the pH of the etching composition may be stabilized to 7 to 9.

A corrosion inhibitor may include a first corrosion inhibitor. The first corrosion inhibitor may include at least one among benzotriazole (BTA) and derivatives thereof. For example, the first corrosion inhibitor may include substituted or unsubstituted benzotriazole. For example, the substituted benzotriazole may be benzotriazole which is substituted with at least one among alkyl of 1 to 4 carbon atoms, amino alkyl of 1 to 4 carbon atoms, phenyl, thiophenyl, halogen, hydroxyl, nitro, thiol and combinations thereof. The alkyl may be linear alkyl or branched alkyl.

The corrosion inhibitor may further include a second corrosion inhibitor which is different from the first corrosion inhibitor. The second corrosion inhibitor may include the above-explained benzotriazole and another one among the derivatives thereof. In another embodiment, the second corrosion inhibitor may include triazole and derivatives thereof. The second corrosion inhibitor may include, for example, 5-methyl benzotriazole, 5-chloro benzotriazole, triazoles, and/or benzotriazole.

If a metal layer other than an etching target is exposed to the etching composition, water may strongly bind to the surface of the metal layer. If the etching composition excludes the first and second corrosion inhibitors, the metal layer may be damaged (for example, corroded) by water. The metal layer may include, for example, copper, cobalt, aluminum, aluminum oxide, and/or alloys thereof. According to embodiments, the etching composition further includes at least one among the first corrosion inhibitor and the second corrosion inhibitor, and the damage of the metal layer may be prevented.

If the corrosion inhibitor includes the first and second corrosion inhibitors, the concentration of the total sum of the first and second corrosion inhibitors may be about 0.1 wt % to about 10 wt %. In detail, the concentration of the total sum of the first and second corrosion inhibitors may be about 0.2 wt % to about 7 wt %. If the etching composition excludes the second corrosion inhibitor, the concentration of the first corrosion inhibitor may be about 0.2 wt % to about 7 wt %. If the concentration of the corrosion inhibitor is less than about 0.2 wt %, a metal layer other than an etching target may be damaged. If the concentration of the corrosion inhibitor is greater than about 7 wt %, solubility limit may be reached and particles and residues may be generated after treatment.

A solubilizer may include a polar aprotic organic solvent. For example, the solubilizer may include dimethyl formamide, dimethyl sulfoxide, dimethyl acetamide, N-methylpyrrolidone, propylene carbonate, sulfolane, tetrahydrofuran, diethylene glycol butyl ether, ethylene glycol monobutyl ether (EGBE), diethylene glycol (DEG) and/or mixtures thereof. The concentration of the solubilizer may be about 5 wt % to about 50 wt %, particularly about 10 wt % to about 30 wt %, preferably about 15 wt % to about 25 wt %.

The solubilizer may be dissolved in water. The solubilizer may improve the solubility of the corrosion inhibitor in water. The solubilizer may cleanse etching residues.

A stabilizer may include a chelating agent. The chelating agent may supply ligands during an etching process. The chelating agent may include a chelating agent including a carboxyl group or a chelating agent including a phosphonate group. For example, the chelating agent may include 1,2-cyclohexylenedinitrilotetraacetic acid (CDTA), N,N,N,N-ethylenediamine-tetrakis (methylenephosphonic acid), ethylenediaminetetraacetic acid (EDTA), 2,2,6,6-tetramethyl-3,5-heptanedione, 1,1,1-trifluoro-2,4-pentanedione, 1,1,1,5,5,5-hexafluoro-2,4-pentanedione, polyaminocarboxylic acid, and/or combinations thereof. The concentration o the chelating agent may be about 0.1 wt % to about 3 wt %. In detail, the concentration of the chelating agent may be about 0.2 wt % to about 1 wt %.

During an etching process, the chelating agent may supply ligands. If the etching composition excludes the chelating agent, metal cations in etching residues may play the role of a catalyst of the decomposition reaction of an oxidizer (for example, hydrogen peroxide). Accordingly, with the progress of the etching process, etching performance may be reduced. Particularly, the etching rate of an etching target layer may be reduced. In addition, the cleaning of etching residues may be degraded. Here, the metal cations may be, for example, titanium ions. The oxidizer may include hydrogen peroxide, and by the decomposition reaction of the oxidizer, oxygen and water may be produced.

According to embodiments, the etching composition may include the chelating agent. The chelating agent may be combined with metal elements/ions during an etching process. The metal ions may be titanium ions. The combination of the chelating agent and the metal elements/ions may include chemical bonding, intermolecular interaction, or physical adsorption. Accordingly, though redeposition of metal ions to the substrate surface during treatment with the etching composition may be prevented by the chelating agent. According to embodiment, though the etching processing time increases, the etching rate of the etching target layer may be maintained, and the etching residues may be cleansed well.

The etching composition may include a residual amount of water as a solvent.

According to embodiments, under the same etching conditions, the etching rate of the etching composition with respect to titanium nitride may be greater than the etching rate of the etching composition with respect to a first metal, and the first metal may include copper, cobalt and aluminum. That is, the etching composition may have a high etching selectivity of titanium nitride with respect to copper, cobalt and aluminum.

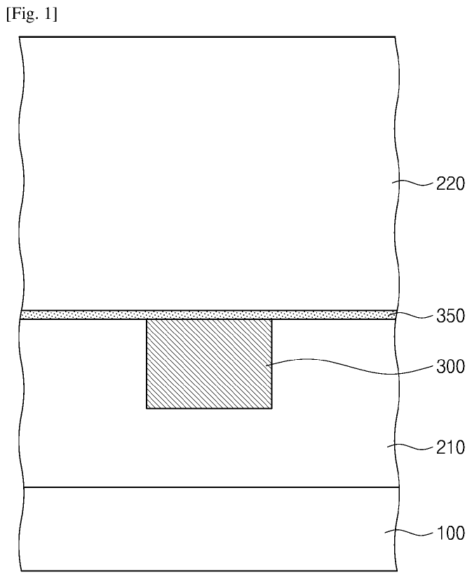

FIG. 1 to FIG. 6 are drawing for explaining the method for manufacturing a semiconductor device using the etching composition according to embodiments.

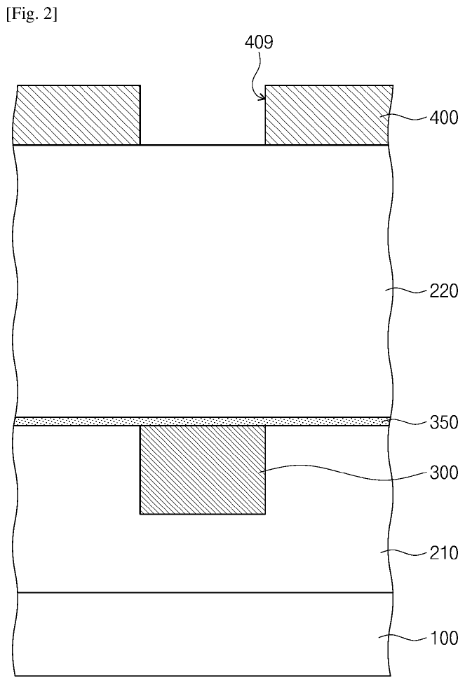

Referring to FIG. 1 and FIG. 2, a first insulating layer 210, a metal pattern 300, an etch stop layer 350, a second insulating layer 220, and a mask pattern 400 may be formed on a substrate 100. The substrate 100 may be a semiconductor substrate. In an embodiment, the substrate 100 may include silicon, germanium, silicon-germanium, or silicon on insulator (SOI). The substrate 100 may include integrated circuits. The integrated circuits may be provided in the substrate 100 or on the top surface of the substrate 100. The integrated circuits may include transistors. The integrated circuits may include logic circuits and memory cells.

The first insulating layer 210 may be formed by a deposition process. The first insulating layer 210 may include a silicon-containing insulating material. The silicon-containing insulating material may include, for example, silicon oxide, silicon nitride, silicon oxynitride, a high density plasma (HDP) oxide layer, tetraethyl orthosilicate (TEOS), plasma enhanced tetraethyl orthosilicate (PE-TEOS), O3-tetraethyl orthosilicate (O3-TEOS), undoped silicate glass (USG), phosphosilicate glass (PSG), borosilicate glass (BSG), borophosphosilicate glass (BPSG), fluoride silicate glass (FSG), spin on glass (SOG), polysilazane layers (e.g., TOSZ), and/or combinations thereof, without limitation. The first insulating layer 210 may be an inter-metal dielectric (IMD). The first insulating layer 210 may be formed by, for example, a deposition process.

The metal pattern 300 may be formed in the first insulating layer 210. The first insulating layer 210 may expose the top surface of the metal pattern 300. The metal pattern 300 may include, for example, copper, cobalt, and/or an alloy thereof. The metal pattern 300 may play the role of a wiring. The metal pattern 300 may be connected with integrated circuits in the substrate 100 via a conductive contact pattern. The conductive contact pattern may be provided on the bottom surface of the metal pattern. A barrier pattern may be further formed between the metal pattern 300 and the first insulating layer 210. For example, the barrier pattern may be provided on the bottom surface and along the side wall of the metal pattern 300, and may not cover the top surface of the metal pattern 300. The barrier pattern may include titanium, titanium nitride, and/or a combination thereof.

The etch stop layer 350 may be formed on the top surface of the first insulating layer 210 and on the top surface of the metal pattern 300. The etch stop layer 350 may cover the top surface of the metal pattern 300. The etch stop layer 350 may include a metal material different from the metal pattern 300. The etch stop layer 350 may include an insulating material including aluminum. For example, the etch stop layer 350 may include aluminum oxide, aluminum oxynitride, and/or aluminum oxycarbide. The thickness of the etch stop layer 350 may be smaller than the thickness of the metal pattern 300.

The second insulating layer 220 may be formed on the etch stop layer 350 by a deposition process. The second insulating layer 220 may include a silicon-containing insulating material.

Referring to FIG. 2, the mask pattern 400 may be formed on the second insulating layer 220. In the mask pattern 400, a guide opening 409 may be formed to expose a portion of the top surface of the second insulating layer 220. The mask pattern 400 may be a hard mask pattern. The mask pattern 400 may include a metal material, for example, titanium and/or titanium nitride.

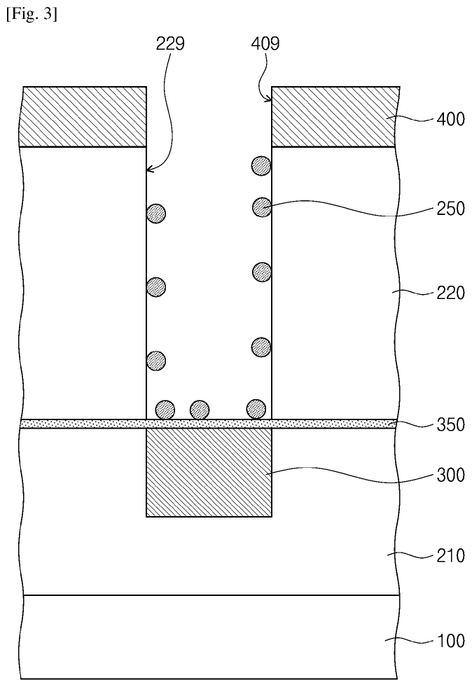

Referring to FIG. 3, an opening 229 may be formed in the second insulating layer 220 to expose the etch stop layer 350. The formation of the opening 229 may be performed by a first etching process. The first etching process may include a dry etching process using an etching gas. The first etching process may be an anisotropic etching process. The portion of the second insulating layer 220 exposed to the mask pattern 400 may be etched to form the opening 229. The mask pattern 400 may not be removed by the first etching process. The portion of the second insulating layer 220 under the mask pattern 400 may not be exposed by the first etching process.

During the first etching process, the etch stop layer 350 may have an etching selectivity with respect to the second insulating layer 220. Accordingly, the etch stop layer 350 may not be removed, and the opening 229 may expose the top surface of the etch stop layer 350.

After finishing the first etching process, etching residues 250 may remain in the opening 229. For example, the etching residues 250 may be provided at the side wall of the opening 229 and on the top surface of the etch stop layer 350 exposed. The etching residues 250 may include the etching residues of the second insulating layer 220 and/or the residues of the etching gas. For example, the etching residues 250 may include the same material as the second insulating layer 220.

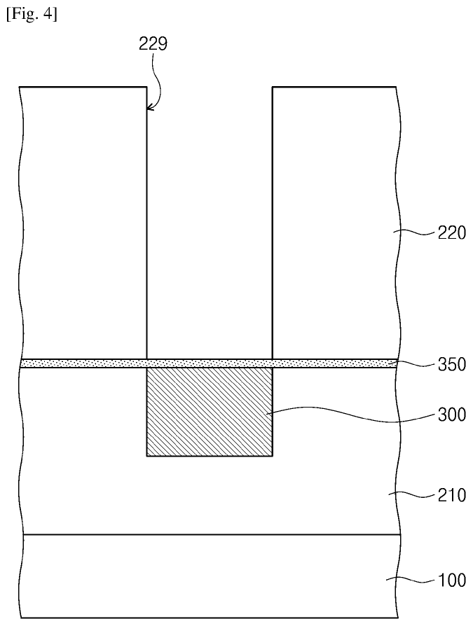

Referring to FIG. 4, a second etching process using the etching composition according to embodiments may be conducted with respect to the mask pattern 400 and the inside of the opening 229. The second etching process may be a wet etching process. By the second etching process, the mask pattern 400 may be removed. The second etching process may be performed so that the etch stop layer 350 and the second insulating layer 220 may have an etching selectivity with respect to the mask pattern 400. For example, the etching rate of the mask pattern 400 may be greater than the etching rate of the etch stop layer 350 and the etching rate of the second insulating layer 220. The second etching process may be performed until the top surface of the second insulating layer 220 is exposed. The etching composition may further remove the etching residues 250. The second etching process may be performed at a temperature of about 25° C. to about 60° C. In detail, the second etching process may be performed at a temperature of about 40° C. to about 60° C. The second etching process may be performed for about 30 seconds to about 10 minutes.

The etching composition may be the same as described above. According to embodiments, the etching composition may include an oxidizer, a pH adjustor, a buffer, a corrosion inhibitor, a solubilizer, a stabilizer, and water. the oxidizer of the etching composition may oxidize titanium or titanium nitride included in the mask pattern 400. For example, the mask pattern 400 may be oxidized to form titanium oxide or titanium oxynitride. Then, titanium oxide or titanium oxynitride may be dissolved in water and removed. According to embodiments, since the concentration of the oxidizer is about 20 wt % or more, the etching rate of the mask pattern 400 may be improved. On the other hand, when the concentration of the oxidizer is greater than 30 wt %, the etching composition becomes unstable and dangerous to handle, and exposed metals may be corroded in the second etching process.

If the pH of the etching composition is less than 7 or greater than 9, the etch stop layer 350 may be damaged. According to embodiments, the etching composition may include a pH adjustor and satisfy the pH conditions of pH 7 to pH 9. Accordingly, the etching of the etch stop layer 350 by the etching composition may be prevented, and the etching rate of the titanium nitride may be improved even further. The etching rate of the mask pattern 400 with respect to the etching rate of the etch stop layer 350 may increase. Since the pH conditions of the etching composition of 7 to 9 are satisfied, the solubility of a corrosion inhibitor in the etching composition may be improved.

The etching composition includes a corrosion inhibitor and may prevent the damage of the etch stop layer 350 by water. If the etch stop layer 350 is porous or inhomogeneous, the etch composition may penetrate to the metal pattern 300 under the etch stop layer 350. In this case, the corrosion inhibitor may prevent oxidation of the metal pattern 300. The concentration of the first corrosion inhibitor may be about 0.2 wt % to about 7 wt %. Since the concentration of the corrosion inhibitor is about 0.2 wt % to about 7 wt %, the corrosion inhibitor may sufficiently protect the metal pattern 300 and the etch stop layer 350.

The solubilizer may improve the solubility of the corrosion inhibitor in water. The solubilizer may clean the etching residues.

Titanium ions may be produced by the etching of the mask pattern 400. That is, titanium ions may be the etching residues of the mask pattern 400. The titanium ions may assist the decomposition of the oxidizer. According to embodiments, the stabilizer may include a chelating agent. The ligands of the chelating agent may capture the titanium ions during the second etching process. Accordingly, the decomposition of the oxidizer by the titanium ions may be prevented. The etching rate of the mask pattern 400 during the second etching process time may be maintained relatively constant by the chelating agent.

Though at least a portion of the metal pattern 300 is exposed to the etching composition, the etching composition has a low etching rate with respect to the metal pattern 300, and undesired etching of the metal pattern 300 may be prevented.

After finishing the second etching process, a washing process using water may be further performed against the substrate 100.

In FIG. 4, the opening 229 is shown to have substantially the same width as the metal pattern 300, but an embodiment of the inventive concept is not limited thereto. For example, the width of the opening 229 may be greater than or smaller than the width of the metal pattern 300.

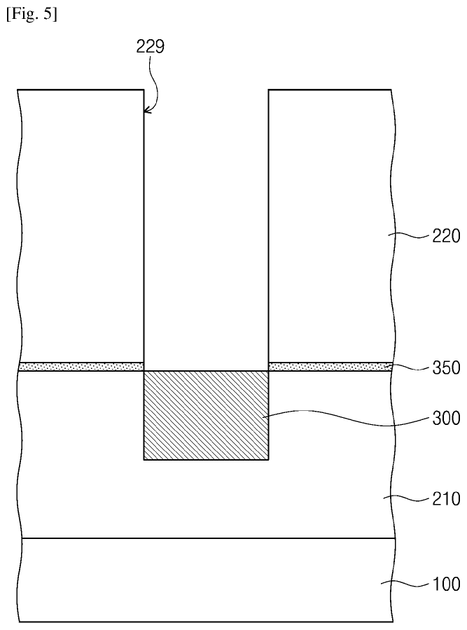

Referring to FIG. 5, the portion of the etch stop layer 350 exposed by the opening 229 may be removed. The removal of the etch stop layer 350 may be performed by a third etching process. The third etching process may be a separate process from the second etching process of FIG. 4. For example, an etchant used in the third etching process may be different from the etching composition according to embodiments. In the third etching process, the second insulating layer 220 and the metal pattern 300 may have an etching selectivity with respect to the etch stop layer 350. Accordingly, the etch stop layer 350 may be partially removed, and the top surface of the metal pattern 300 may be exposed. After finishing the third etching process, the other portions of the etch stop layer 350 may remain between the first insulating layer 210 and the second insulating layer 220.

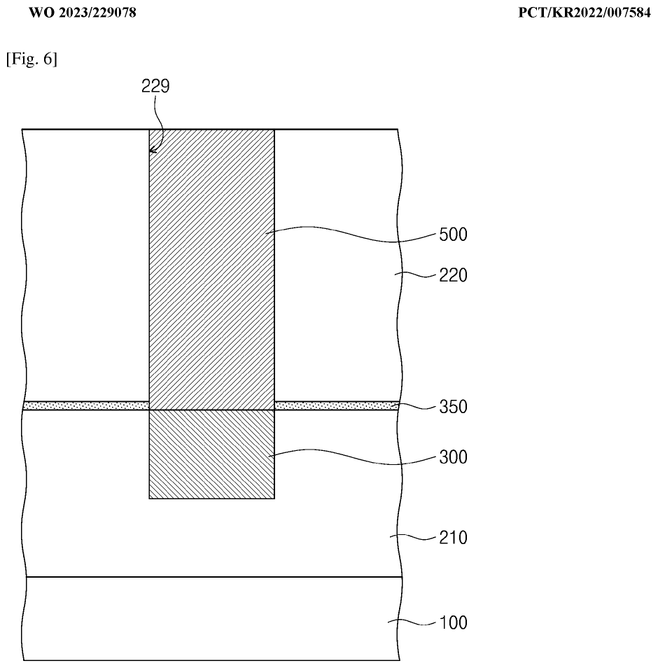

Referring to FIG. 6, a conductive pattern 500 may be formed in the second insulating layer 220 to fill up the opening 229. For example, the conductive pattern 500 may be formed by electroplating a metal. The metal may include copper, cobalt, and/or tungsten. The formation of the conductive pattern 500 may include forming a conductive layer on the top surface of the second insulating layer 220 and in the opening 229 and removing the upper portion the conductive layer. The removal of the upper portion of the conductive layer may be performed by a chemical mechanical polishing process. As a result of removing the upper portion of the conductive layer, the top surface of the second insulating layer 220 may be exposed, and the conductive pattern 500 may be formed. Accordingly, the conductive pattern 500 may be delocalized in the opening 229. The conductive pattern 500 may cover the metal pattern 300. The conductive pattern 500 may be a via or a wiring. The conductive pattern 500 may be electrically connected with integrated circuits on the substrate 100 through the metal pattern 300. By the manufacturing example explained up to now, the manufacture of a semiconductor device may be completed.

Hereinafter, referring to experimental embodiments of the inventive concept and comparative embodiments, an etching composition and an etching process using the same will be explained.

### 1. Preparation of Etching Composition

Table 1 shows evaluation results on the etching rates of titanium nitride layers using the etching compositions of Experimental Example 1-1 to Experimental Example 1-6, Comparative Example 1-1 and Comparative Example 1-2.

TABLE 1

| | Concentration | Etching rate of |
|---|---|---|
| | of hydrogen | titanium nitride |
| | peroxide (wt %) | layer (Å/min) |
| Experimental | 27.9 | 232.2 |
| Example 1-1 | | |
| Experimental | 26.4 | 224.8 |
| Example 1-2 | | |
| Experimental | 24.8 | 216.6 |
| Example 1-3 | | |
| Experimental | 23.3 | 197 |
| Example 1-4 | | |
| Experimental | 21.7 | 184 |
| Example 1-5 | | |
| Experimental | 20.2 | 172.6 |
| Example 1-6 | | |
| Comparative | 18.6 | 162.6 |
| Example 1-1 | | |
| Comparative | 15.5 | 157 |
| Example 1-2 | | |

Referring to Table 1, Experimental Example 1-1 to Experimental Example 1-6 show higher etching rates of titanium nitride layers than Comparative Example 1-1 and Comparative Example 1-2. According to the Examples, the etching composition includes about 20 wt % or more of an oxidizer, and the etching rate of the titanium nitride layer may increase. With the increase of the concentration of hydrogen peroxide, the etching rate of the titanium nitride layer may increase. Though the etching time passed, it was observed that the etching rates of Experimental Example 1-1 to Experimental Example 1-6 were maintained relatively constant.

Table 2 shows evaluation results on the etching rates of titanium nitride layers using the etching compositions of Experimental Example 2-1 to Experimental Example 2-3, and Comparative Examples 2 and 3. In Table 2, TAAH is tetraalkylammonium hydroxide.

TABLE 2

| | Concentration of TAAH | | Etching rate of titanium |
|---|---|---|---|
| | (wt %) | pH | nitride layer (Å/min) |
| Comparative | 0 | 4.2 | 81.6 |
| Example 2 | | | |
| Comparative | 1.5 | 7.1 | 115.7 |
| Example 3 | | | |
| Experimental | 3 | 7.3 | 125.0 |
| Example 2-1 | | | |
| Experimental | 4.5 | 7.6 | 125.6 |
| Example 2-2 | | | |
| Experimental | 9.25 | 7.9 | 152.8 |
| Example 2-3 | | | |

Referring to Table 2, the etching rates of the titanium nitride layers using the etching compositions of Experimental Example 2-1 to Experimental Example 2-3 may be greater than the etching rate of the titanium nitride layer using the etching compositions of Comparative Example 2 and 3. The etching compositions of Experimental Example 2-1 to Experimental Example 2-3 include about 3 wt % to about 10 wt % of TAAH, have a pH of 6 to 9, and have a TiN etch rate greater than 120 Å/min. Comparative Example 2 does not include TAAH, and concentration of TAAH in Comparative Example 3 is less than 3 wt %. According to the Examples, the pH adjustor and the concentration thereof were controlled, and an etching composition having a pH of 7 to 9 could be prepared. The etching rate of a silicon nitride layer using the etching composition may be improved.

Table 3 shows evaluation results on the etching rates of the titanium nitride layers using the etching compositions of Comparative Example 4 and Experimental Example 3-1 to 3-4, the etching rates of metals (Cu and Co), and pH stability.

TABLE 3

| | | Etch rate of | | | | pH |
|---|---|---|---|---|---|---|
| | Buffer | TiN layer | | Cu ER | Co ER | (stable+) |
| | Conc. | (Å/min) | pH | (Å/min) | (Å/min) | (not stable−) |
| Comparative | 0 | 166.2 | 7.53 | 1.7 | 1 | − |
| Example 4 | | | | | | |
| Experimental | 1 w % | 227.2 | 7.52 | 2.3 | 0.1 | +/− |
| Example 3-1 | | | | | | |
| Experimental | 2 w % | 236.4 | 7.50 | 2.6 | 0 | + |
| Example 3-2 | | | | | | |
| Experimental | 3 w % | 238.6 | 7.50 | 2.7 | 0.1 | + |
| Example 3-3 | | | | | | |
| Experimental | 5 w % | 243.4 | 7.53 | 4.0 | 0.2 | + |
| Example 3-4 | | | | | | |

Referring to Table 3, the etching composition of Comparative Example 4, which does not contain the buffer of the present invention, has an unstable pH and a low TiN etching rate. According to Experimental Examples 3-1 to 3-4, as the concentration of the buffer in the etching composition increased from 1 wt % to 5 wt %, the TiN etching rate increased and the pH stability increased.

Table 4 shows evaluation results on the concentration of hydrogen peroxide according to the time using the etching compositions of Experimental Example 5-1 to Experimental Example 5-6 and Comparative Example 6.

TABLE 4

| | | | | Concentration of hydrogen | | | |
|---|---|---|---|---|---|---|---|
| | Stabilizer | Etching rate of | | peroxide according to time | | | |
| Etching | (chelating | TiN layer | | (wt %) | | | |
| composition | agent) | (Å/min) | pH | 0 h | 4 h | 8 h | 24 h |
| Experimental | Carboxylate | 232.2 | 7.48 | 28.3 | 28.1 | 26.3 | 19.7 |
| Example 5-1 | type | | | | | | |
| Experimental | | 231.4 | 7.43 | 28.3 | 26.6 | 24.8 | 13.7 |
| Example 5-2 | | | | | | | |
| Experimental | | 231 | 7.49 | 28.3 | 25.9 | 23 | 12.1 |
| Example 5-3 | | | | | | | |
| Experimental | Phosphonate | 244.8 | 7.45 | 28.2 | 23.6 | 18.6 | 7.5 |
| Example 5-4 | type | | | | | | |
| Experimental | | 238.6 | 7.42 | 28.3 | 27.1 | 25.7 | 14.4 |
| Example 5-5 | | | | | | | |
| Experimental | | 238.6 | 7.46 | 28.2 | 27.2 | 25.8 | 14.4 |
| Example 5-6 | | | | | | | |
| Comparative | — | 276.8 | 7.52 | — | — | — | — |
| Example 6 | | | | | | | |

Referring to Table 4, in the etching process of titanium nitride layer using each of the etching compositions of Experimental Example 5-1 to Experimental Example 5-6, it could be confirmed that the concentration of hydrogen peroxide was maintained relatively constant with the lapse of time. Each of the etching compositions of Experimental Example 5-1 to Experimental Example 5-6 may include a stabilizer. The etching composition of Comparative Example 5 did not include a stabilizer. In the etching process of a titanium nitride layer using the etching composition of Comparative Example 6, it was evaluated that hydrogen peroxide was not left.

According to the Examples, the etching composition includes a stabilizer and may prevent the decomposition of hydrogen peroxide and stabilize hydrogen peroxide. Accordingly, though time passes, the etching composition may etch a titanium nitride layer. In addition, the etching composition may be reused.

Although the embodiments of the present invention have been described, it is understood that the present invention should not be limited to the embodiments, but various changes and modifications can be made by one ordinary skilled in the art within the spirit and scope of the present invention as hereinafter claimed.

1. An etching composition comprising:
about 20 wt % to about 30 wt % of an oxidizer;
a buffer comprising at least one compound selected from the group consisting of an ammonium phosphate, and a material represented by the following Formula 1; 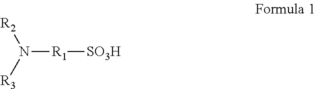
wherein in Formula 1, R₁ is alkyl of 1 to 8 carbon atoms, and R₂ and R₃ are each independently hydrogen, alkyl of 1 to 3 carbon atoms, or hydroxyalkyl of 1 to 8 carbon atoms, or R₂ and R₃ are connected with each other to form a connected heterocyclic structure of 2 to 8 carbon atoms, and
wherein in Formula 1, at least one of R₂ or R₃ is hydroxyalkyl of 1 to 8 carbon atoms, or R₂ and R₃ have a connected heterocyclic structure of 2 to 8 carbon atoms with each other; and
about 3 wt % to about 10 wt % of a pH adjustor comprising tetraalkyl ammonium hydroxide,
wherein the etching composition has a pH of 7 to 9.

2. The etching composition of claim 1, wherein the buffer comprises an ammonium phosphate selected from the group consisting of diammonium hydrogen phosphate ((NH₄)₂HPO₄), ammonium dihydrogen phosphate ((NH₄)H₂PO₄), and triammonium phosphate ((NH₄)₃PO₄).

3. The etching composition of claim 1, wherein the buffer comprises the material represented by Formula 1.

4. The etching composition of claim 3, wherein, in Formula 1, R₂ and R₃ are connected with each other to form a connected heterocyclic structure of 2 to 8 carbon atoms, and
the connected heterocyclic structure comprises at least one oxygen or nitrogen atom.

5. The etching composition of claim 3, wherein, in Formula 1, at least one of R₂ or R₃ is a hydroxyalkyl of 1 to 8 carbon atoms.

6. The etching composition of claim 1, wherein the buffer comprises at least one of N-[tris(hydroxymethyl)methyl]-2-aminoethansulfonic acid (TES), 4-(N-morpholino)butanesulfonic acid (MOBS), or N-[tris(hydroxymethyl)methyl]-3-aminopropanesulfonic acid (TABS).

7. The etching composition of claim 1, wherein, under a set of etching conditions, an etching rate of the etching composition with respect to titanium nitride is greater than an etching rate of the etching composition with respect to a first metal, and
wherein the first metal comprises copper, cobalt and aluminum.

8. The etching composition of claim 1, further comprising:
a corrosion inhibitor comprising at least one of a benzotriazole or derivatives thereof; and
a chelating agent.

9. The etching composition of claim 8, wherein
a concentration of the pH adjustor is about 4 wt % to about 7 wt %,
a concentration of the corrosion inhibitor is about 0.2 wt % to about 7 wt %, and
a concentration of the chelating agent is about 0.2 wt % to about 1 wt %.

10. The etching composition of claim 8, further comprising:
a solubilizer comprising at least one compound selected from the group consisting of dimethyl formamide, dimethyl sulfoxide, dimethyl acetamide, N-methylpyrrolidone, propylene carbonate, sulfolane, tetrahydrofuran, diethylene glycol butyl ether, ethylene glycol monobutyl ether (EGBE), and diethylene glycol (DEG), and mixtures thereof, and
water.

11. The etching composition of claim 1, wherein a concentration of the buffer is about 1.5 wt % to about 5 wt %.

12. An etching composition comprising:
about 20 wt % to about 30 wt % of an oxidizer;
a buffer in a concentration of about 1 wt % to about 10 wt %, the buffer comprising at least one compound selected from the group consisting of an ammonium phosphate and a material represented by Formula 1, 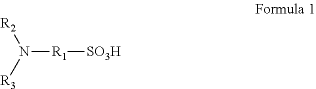
wherein in Formula 1, R₁ is alkyl of 1 to 8 carbon atoms, and R₂ and R₃ are each independently hydrogen, alkyl of 1 to 3 carbon atoms, or hydroxyalkyl of 1 to 8 carbon atoms, or R₂ and R₃ are connected with each other to form a connected heterocyclic structure of 2 to 8 carbon atoms, and
in Formula 1, at least one of R₂ or R₃ is hydroxyalkyl of 1 to 8 carbon atoms, or R₂ and R₃ have a connected heterocyclic structure of 2 to 8 carbon atoms with each other;
a pH adjustor comprising alkyl ammonium hydroxide, a concentration of the pH adjustor being about 3 wt % to about 10 wt %;
a corrosion inhibitor comprising substituted or unsubstituted benzotriazole, a concentration of the corrosion inhibitor being about 0.1 wt % to about 10 wt %;
a chelating agent comprising a carboxylate group or a phosphonate group, a concentration of the chelating agent being about 0.1 wt % to about 3 wt %;
a solubilizer comprising a polar aprotic organic solvent, a concentration of the solubilizer being about 15 wt % to about 25 wt %; and
water,
wherein the etching composition has a pH of 7 to 9.

13. The etching composition of claim 12, wherein the buffer comprises an ammonium phosphate selected from the group consisting of diammonium hydrogen phosphate ((NH₄)₂HPO₄), ammonium dihydrogen phosphate ((NH₄)H₂PO₄), and triammonium phosphate ((NH₄)₃PO₄).

14. The etching composition of claim 12, wherein the buffer comprises the material represented by Formula 1.

15. The etching composition of claim 12, wherein the buffer comprises at least one of N-[tris(hydroxymethyl)methyl]-2-aminoethansulfonic acid (TES), 4-(N-morpholino)butanesulfonic acid (MOBS), or N-[tris(hydroxymethyl)methyl]-3-aminopropanesulfonic acid (TABS).

16. The etching composition of claim 12, wherein
the oxidizer comprises at least one compound selected from the group consisting of hydrogen peroxide, peroxide urea, peroxydisulfuric acid, ammonium persulfate, peroxymonosulfuric acid, pyrosulfuric acid, and ozone, and mixtures thereof,
the pH adjustor comprises tetramethyl ammonium hydroxide or tetraethyl ammonium hydroxide,
the chelating agent comprises at least one compound selected from the group consisting of 1,2-cyclohexylenedinitrilotetraacetic acid (CDTA), N,N,N,N-ethylenediamine-tetrakis (methylenephosphonic acid), ethylenediaminetetraacetic acid (EDTA), 2,2,6,6-tetramethyl-3,5-heptanedione, 1,1,1-trifluoro-2,4-pentanedione, 1,1,1,5,5,5-hexafluoro-2,4-pentanedione, and polyaminocarboxylic acid, and combinations thereof, and
the solubilizer comprises at least one compound selected from the group consisting of dimethyl formamide, dimethyl sulfoxide, dimethyl acetamide, N-methylpyrrolidone, propylene carbonate, sulfolane, tetrahydrofuran, diethylene glycol butyl ether, ethylene glycol monobutyl ether (EGBE), and diethylene glycol (DEG), and mixtures thereof.

17. A method for manufacturing a semiconductor device, the method comprising:
preparing a substrate, a first insulating layer on the substrate, a metal pattern on the first insulating layer, an etch stop layer covering a top surface of the metal pattern, a second insulating layer on the first insulating layer, and a mask pattern on a top surface of the second insulating layer;
performing a first etching process on the top surface of the second insulating layer exposed by the mask pattern to form an opening exposing the etch stop layer; and
performing a second etching process using the etching composition according to claim 10 with respect to the mask pattern and in the opening to remove the mask pattern,
wherein the mask pattern has an etching selectivity with respect to the etch stop layer during the second etching process.

18. The method for manufacturing a semiconductor device of claim 17, wherein the opening exposes a top surface of the etch stop layer after finishing the second etching process.

19. The method for manufacturing a semiconductor device of claim 17, wherein the mask pattern comprises titanium nitride, and
the etch stop layer comprises an insulating material comprising aluminum.

20. The method for manufacturing a semiconductor device of claim 17, wherein the first etching process further comprises forming etching residues in the opening, and
the second etching process further comprises removing of the etching residues.
